(19) United States
(12) Patent Application Publication
(10) Pub. No.: US 2011/0300669 A1
(43) Pub. Date: Dec. 8, 2011

(54) Method for Making Die Assemblies

(76) Inventors: Chi-Chih Shen, Kaohsiung (TW); Jen-Chuan Chen, Kaohsiung (TW); Hui-Shan Chang, Kaohsiung (TW); Chia-Lin Hung, Kaohsiung (TW); Ying-Sheng Chuang, Kaohsiung (TW)

(21) Appl. No.: 12/795,315

(22) Filed: Jun. 7, 2010

(51) Int. Cl. H01L 21/50

(52) U.S. Cl. 438/107; 257/E21.499

(57) ABSTRACT

The present invention relates to a method for making chip assemblies, including the following steps of: (a) providing a tested upper wafer and at least one tested lower wafer; (b) sawing the at least one tested lower wafer to form a plurality of lower dice, the lower dice including a plurality of know good lower dice; (c) picking up and rearranging the know good lower dice on a carrier according to the wafer map of the upper wafer; (d) bonding the upper wafer and the carrier; (e) removing the carrier; and (f) proceeding sawing step. Whereby, the dice of the die assembly are both known good dice, thus the yield loss caused by the different yields between the upper wafer and the lower wafer will not occur.

### BACKGROUND OF THE INVENTION

1. Field of the Invention

The present invention relates to a method for making die assemblies, and more particularly to a method including wafer-to-wafer stacking for making die assemblies.

2. Description of the Related Art

There are two conventional stacking technologies adopted in three-dimensional IC package method: one is Wafer-to-Wafer (WtW) stacking; the other is Chip-to-Chip (CtC) stacking or Chip-to-Wafer (CtW) stacking. Compared with the Chip-to-Chip (CtC) stacking or the Chip-to-Wafer (CtW) stacking, the Wafer-to-Wafer (WtW) stacking is a package method that can achieve high production rate and simple manufacturing process.

However, the major advantage of the Wafer-to-Wafer (WtW) stacking is that the yield rate of the final product is affected by the yields of the upper wafer and the lower wafer. For example, the yields of two wafers to be stacked are 50% and 100% respectively. Even one of the wafers has a higher yield (100%), the yield rate of the final product is still only 50% after the two wafers are stacked directly. Thus, the yield loss reaches 50%. Consequently, the yield rate of the final product can be significantly raised only when the manufacturing processes of the upper wafer and the lower wafer are very stable.

Therefore, it is necessary to provide a method for making die assemblies to solve the above problems.

### SUMMARY OF THE INVENTION

The present invention is directed to a method for making die assembly, comprising the following steps of: (a) providing a tested upper wafer and at least one tested lower wafer, the tested upper wafer having a plurality of upper known good dice; (b) sawing the at least one tested lower wafer to form a plurality of lower dice, the lower dice including a plurality of lower known good dice; (c) picking up and rearranging the lower known good dice on a carrier, wherein the positions of the lower known good dice correspond to the positions of the upper known good dice; (d) bonding the tested upper wafer to the carrier, so that the lower known good dice are electrically connected to the upper known good dice; (e) removing the carrier; and (f) proceeding a sawing step to form a plurality of die assemblies.

Whereby, the lower known good dice are rearranged according to the wafer mapping of the tested upper wafer, thus, the dice of the die assembly are ensured to be both known good dice. Therefore, the yield loss of the product caused by the different yields between the upper wafer and the lower wafer will not occur.

### BRIEF DESCRIPTION OF THE DRAWINGS

FIGS. 1 to 15 are schematic views of a method for making die assemblies according to the present invention.

### DETAILED DESCRIPTION OF THE INVENTION

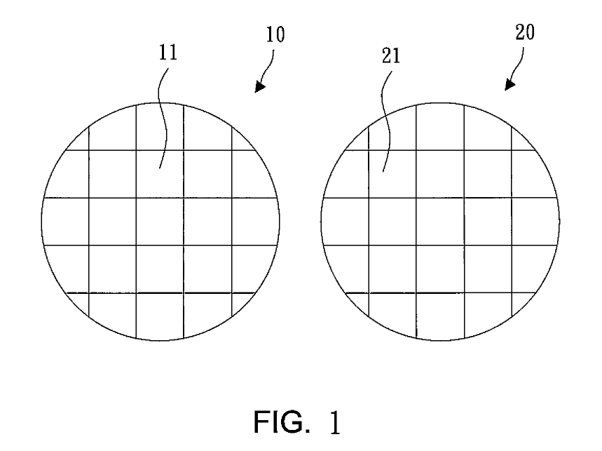

FIGS. 1 to 15 show schematic views of a method for making die assemblies according to the present invention. As shown in FIG. 1, an upper wafer 10 and at least one lower wafer 20 are provided. The upper wafer 10 and the lower wafer 20 have been tested, and have their wafer mappings, wherein the tested upper wafer 10 has a plurality of upper known good dice 11 and a plurality of upper known bad dice (not shown).

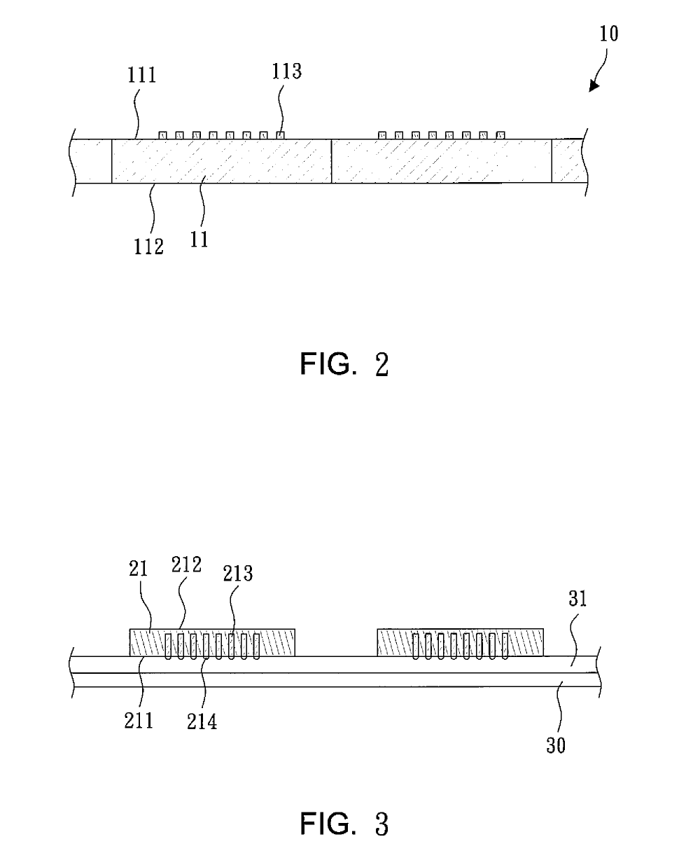

As shown in FIG. 2, the upper known good die 11 has a major surface 111, a back surface 112 and a plurality of conducting elements 113. The conducting elements 113, for example, bumps, are disposed adjacent to the major surface 111 of the upper known good die 11.

Then, the at least one tested lower wafer 20 is sawed to form a plurality of lower dice. The lower dice including a plurality of lower known good dice 21 (FIG. 3) and a plurality of lower known bad dice (not shown).

As shown in FIG. 3, the lower known good die 21 has a major surface 211, a back surface 212, a plurality of vias 213 and a plurality of bumps 214. The vias 213 are disposed in the lower known good die 21. The bumps 214 are disposed adjacent to the major surface 211 of the lower known good die 21. The vias 213 are electrically connected to the bumps 214.

Then, the lower known good dice 21 are picked up and rearranged on a carrier 30, wherein the positions of the lower known good dice 21 correspond to the positions of the upper known good dice 11. That is, the wafer mapping of the carrier 30 after rearranging the lower known good dice 21 is the same as that of the tested upper wafer 10. In the embodiment, the carrier 30 is a dummy wafer without any function, and the major surfaces 211 of the lower known good dice 21 are adhered to the carrier 30 by using an adhesion layer 31.

In the embodiment, the lower known good dice 21 are picked up to disposed and arranged on the carrier 30. However, it is to be understood that the lower known bad dice can also be picked up and rearranged on the carrier so as to fill up the spaces between the lower known good dice 21, wherein the positions of the lower known bad dice correspond to the positions of the upper known bad dice.

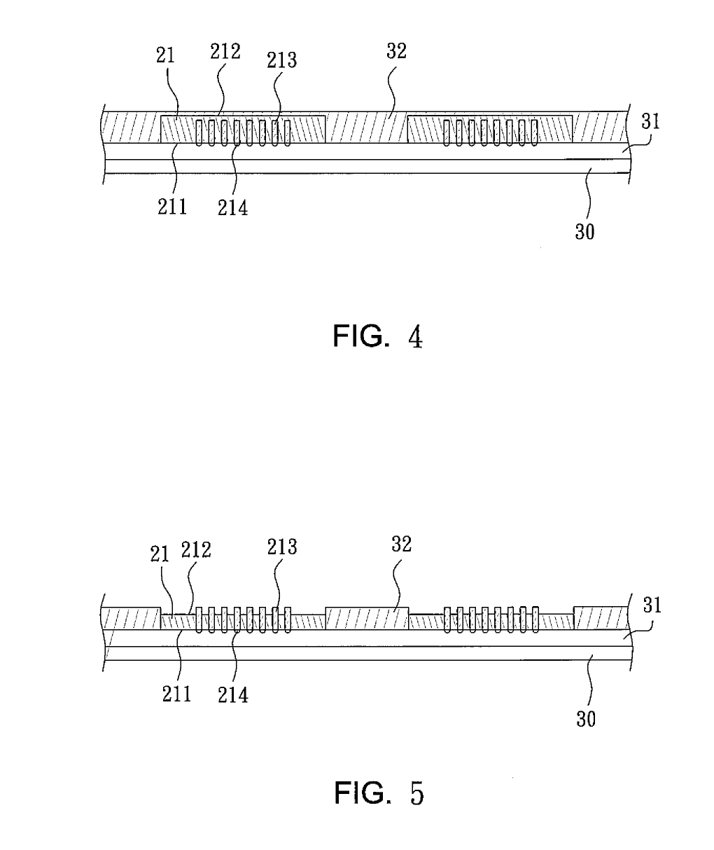

As shown in FIG. 4, an insulation layer 32 is formed on the lower known good dice 21 to encapsulate the lower known good dice 21. Preferably, the insulation layer 32 is a kind of molding compound and fills up the gaps between the lower known good dice 21.

As shown in FIG. 5, the top surface of the insulation layer 32 is ground to expose the lower known good dice 21, and parts of the back surfaces 212 of the lower known good dice 21 are removed by etching so as to expose ends of the vias 213.

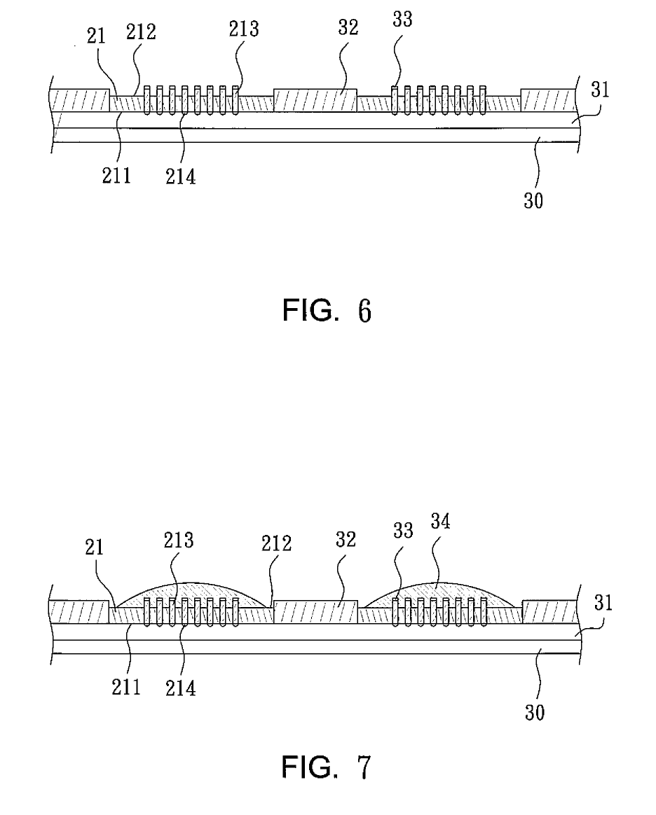

As shown in FIG. 6, the exposed ends of the vias 213 are surface finished to form a surface finish layer 33.

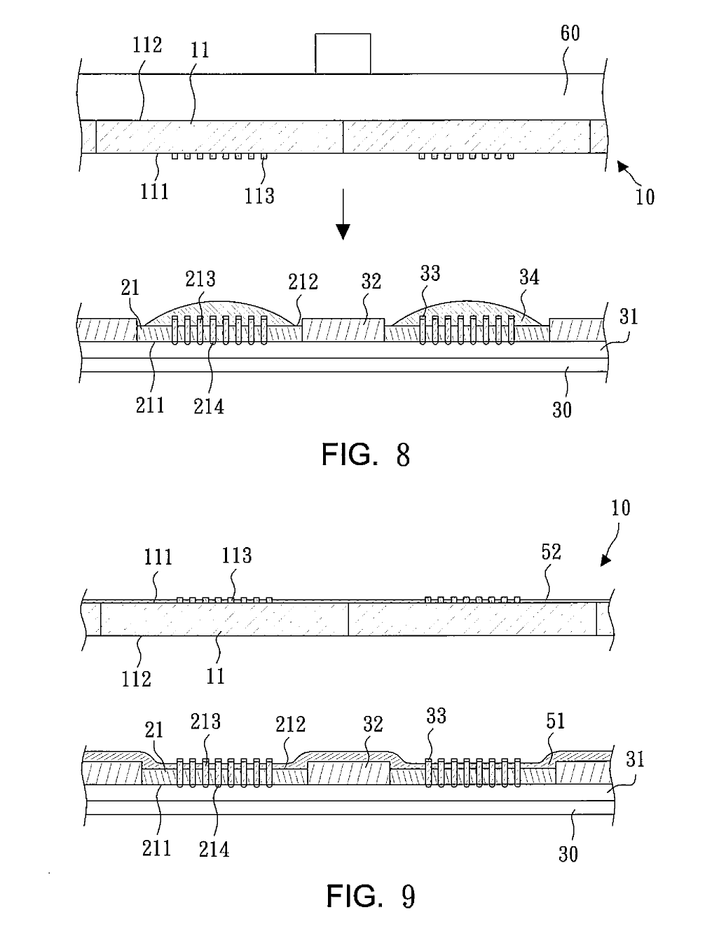

As shown in FIGS. 7 and 8, the upper wafer 10 is bonded to the carrier 30, so that the lower known good dice 21 are electrically connected to the upper known good dice 11. In the embodiment, an underfill 34 is formed on the lower known good dice 21 by dispensing (FIG. 7). Then, the tested upper wafer 10 is thermally bonded to the carrier 30 by using a suction head 60 (FIG. 8), so that the vias 213 of the lower known good dice 21 are electrically connected to the conducting elements 113 of the upper known good dice 11. Meanwhile, the underfill 34 becomes an intermediate adhesion layer 35.

In the embodiment, the intermediate adhesion layer 35 is formed by dispensing. However, in other embodiment, the intermediate adhesion layer 35 may be formed by the following steps.

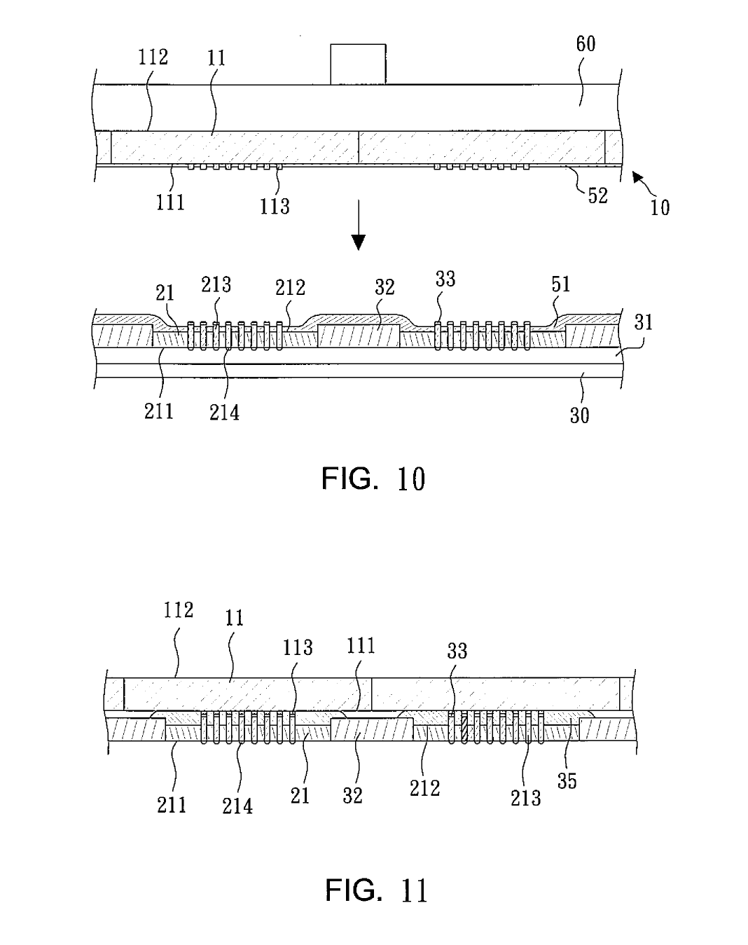

As shown in FIG. 9, a first film 51 is adhered on the lower known good dice 21. Then, UV light is applied to cure the first film 51. Part of the surface of the first film 51 is removed, so as to expose the vias 213. In addition, a second film 52 is adhered on the tested upper wafer 10. The material of the first film 51 and the second film 52 are the same, and the first film 51 and the second film 52 are whole pieces of thin films. Then, UV light is applied to cure the second film 52. Part of the surface of the second film 52 is removed by etching, so as to expose the conducting elements 113. Then, the tested upper wafer 10 is thermally bonded to the carrier 30 by using a suction head 60 (FIG. 10), so that the vias 213 of the lower known good dice 21 are electrically connected to the conducting elements 113 of the upper known good dice 11 (FIG. 11). Meanwhile, the first film 51 and the second film 52 form a same layer (i.e., the intermediate adhesion layer 35).

As shown in FIG. 11, the suction head 60, the carrier 30 and the adhesion layer 31 are removed.

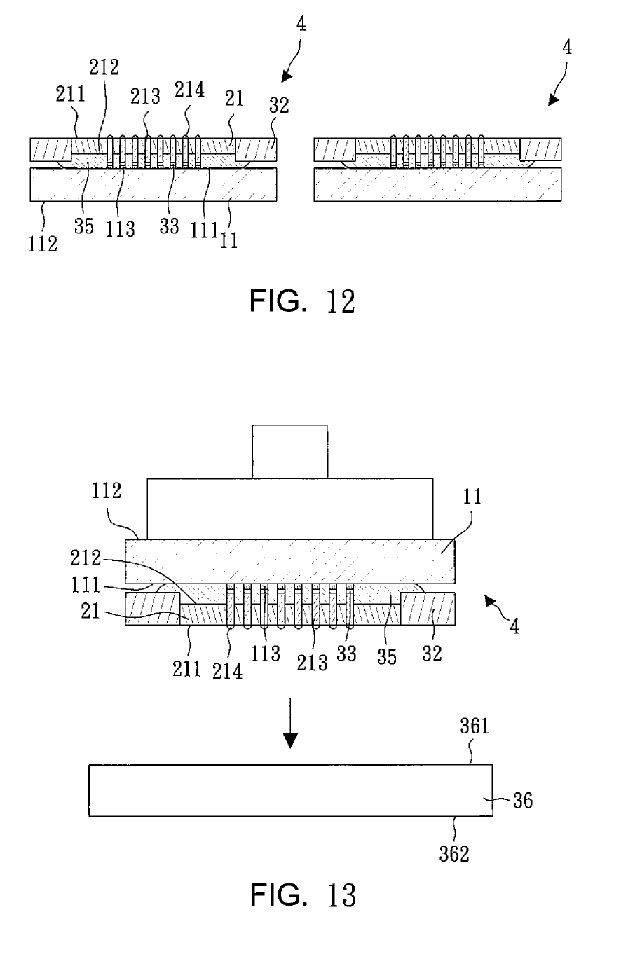

As shown in FIG. 12, a sawing step is proceeded to saw the tested upper wafer 10 and the insulation layer 32 to form a plurality of die assemblies 4.

In the present invention, the lower known good dice 21 are rearranged on the carrier 30 according to the wafer mapping of the tested upper wafer 10, thus, the dice 11, 21 of the die assembly 4 are ensured to be both known good dice. Therefore, the yield loss of the product caused by the different yields between the upper wafer and the lower wafer will not occur.

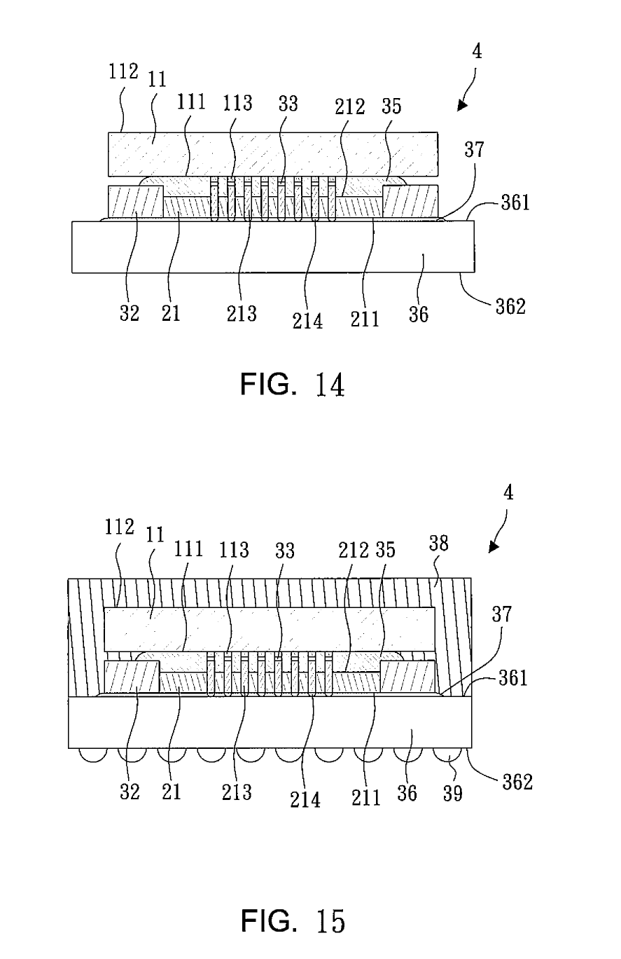

In the present invention, the die assemblies 4 can be proceeded with the following steps. As shown in FIG. 13, the die assemblies 4 are electrically connected to a substrate 36. In the embodiment, the substrate 36 has a top surface 361 and a bottom surface 362. The bumps 214 of the lower known good dice 21 are electrically connected to the top surface 361 of the substrate 36. Then, as shown in FIG. 14, a lower adhesion layer 37 is formed on the major surface 211 of the lower known good die 21 and the top surface 361 of the substrate 36, so as to protect the bumps 214.

As shown in FIG. 15, a molding compound 38 is formed to encapsulate the die assemblies 4. In the embodiment, the molding compound 38 encapsulates the top surface 361 of the substrate 36, the upper known good dice 11, the insulation layer 32, the intermediate adhesion layer 35 and the lower adhesion layer 37. Finally, a plurality of solder balls 39 are formed on the bottom surface 362 of the substrate 36, and the substrate 36 and the molding compound 38 are sawed.

FIG. 15 shows a cross-sectional view of a die assembly according to the present invention. The die assembly 4 comprises an upper known good dice 11, a lower known good dice 21, an insulation layer 32 and an intermediate adhesion layer 35. Preferably, the die assembly 4 further comprises a substrate 36, a lower adhesion layer 37, a molding compound 38 and a plurality of solder balls 39.

The upper known good die 11 has a major surface 111, a back surface 112 and a plurality of conducting elements 113. The conducting elements 113, for example, bumps, are disposed adjacent to the major surface 111 of the upper known good die 11.

The lower known good die 21 has a major surface 211, a back surface 212, a plurality of vias 213 and a plurality of bumps 214. The vias 213 penetrate the lower known good die 21. The bumps 214 are disposed adjacent to the major surface 211 of the lower known good die 21. The vias 213 are electrically connected to the bumps 214. The back surface 212 of the lower known good die 21 faces the major surface 111 of the upper known good die 11, and the vias 213 protrude from the back surface 212 of the lower known good die 21 so that the vias 213 of the lower known good dice 21 are electrically connected to the conducting elements 113 of the upper known good dice 11. Preferably, a surface finish layer 33 is disposed at the ends of the vias 213.

The insulation layer 32 encapsulates the periphery of the lower known good die 21. In the embodiment, the insulation layer 32 is a molding compound, and encapsulates four sides of the lower known good die 21. The side of the insulation layer 32 is aligned with the side of the upper known good dice 11. The bottom surface of the insulation layer 32 is aligned with the major surface 211 of the lower known good die 21. The thickness of the lower known good die 21 is smaller than that of the insulation layer 32

The intermediate adhesion layer 35 is disposed between the back surface 212 of the lower known good die 21 and the major surface 111 of the upper known good die 11 to protect the vias 213 and the conducting elements 113. The intermediate adhesion layer 35 includes but is not limited to the two following types. First, the intermediate adhesion layer 35 is an underfill that is formed by dispensing; second, the intermediate adhesion layer 35 is formed by combining two films, such as the first film 51 and the second film 52 in FIG. 9.

The substrate 36 has a top surface 361 and a bottom surface 362. The bumps 214 of the lower known good dice 21 are electrically connected to the top surface 361 of the substrate 36. The lower adhesion layer 37 is disposed on the major surface 211 of the lower known good die 21 and the top surface 361 of the substrate 36, so as to protect the bumps 214. The molding compound 38 encapsulates the top surface 361 of the substrate 36, the upper known good dice 11, the insulation layer 32, the intermediate adhesion layer 35 and the lower adhesion layer 37. The solder balls 39 are disposed on the bottom surface 362 of the substrate 36.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined by the appended claims.

What is claimed is:

1. A method for making die assembly, comprising the following steps of:
(a) providing a tested upper wafer and at least one tested lower wafer, the tested upper wafer having a plurality of upper known good dice;
(b) sawing the at least one tested lower wafer to form a plurality of lower dice, the lower dice including a plurality of lower known good dice;
(c) picking up and rearranging the lower known good dice on a carrier, wherein the positions of the lower known good dice correspond to the positions of the upper known good dice;
(d) bonding the tested upper wafer to the carrier, so that the lower known good dice are electrically connected to the upper known good dice;
(e) removing the carrier; and
(f) proceeding a sawing step to form a plurality of die assemblies.

2. The method as claimed in claim 1, wherein in step (b), each of the lower known good dice has a major surface, a back surface, a plurality of vias and a plurality of bumps, the vias are disposed in the lower known good die, the bumps are disposed adjacent to the major surface of the lower known good die and electrically connected to the vias, and in step (c), the major surfaces of the lower known good dice are adhered to the carrier by using an adhesion layer.

3. The method as claimed in claim 2, further comprising a step of removing part of the back surfaces of the lower known good dice so as to expose ends of the vias after step (c).

4. The method as claimed in claim 1, further comprising a step of forming an insulation layer on the lower known good dice to encapsulate the lower known good dice, and a step of grinding a surface of the insulation layer to expose the lower known good dice after step (c).

5. The method as claimed in claim 2, wherein in step (a), each of the upper known good dice has a major surface, a back surface and a plurality of conducting elements, the conducting elements are disposed adjacent to the major surface of the upper known good die, the step (d) comprises the steps of forming an underfill on the lower known good dice by dispensing, then thermally bonding the tested upper wafer to the carrier, so that the vias of the lower known good dice are electrically connected to the conducting elements of the upper known good dice.

6. The method as claimed in claim 2, wherein in step (a), each of the upper known good dice has a major surface, a back surface and a plurality of conducting elements, the conducting elements are disposed adjacent to the major surface of the upper known good die, the step (d) comprises the following steps of:
(d1) adhering a first film on the lower known good dice;
(d2) curing the first film;
(d3) removing part of the surface of the first film, so as to expose the vias;
(d4) adhering a second film on the tested upper wafer, wherein the material of the first film and the second film are the same;
(d5) curing the second film;
(d6) removing part of the surface of the second film, so as to expose the conducting elements; and
(d7) thermally bonding the tested upper wafer to the carrier, so that the vias of the lower known good dice are electrically connected to the conducting elements of the upper known good dice, and the first film and the second film form a same layer.

7. The method as claimed in claim 1, wherein the tested upper wafer in step (a) further includes a plurality of upper known bad dice, the tested lower wafer in step (b) further includes a plurality of lower known bad dice, in step (c), the lower known bad dice are rearranged on the carrier, so that the positions of the lower known bad dice correspond to the positions of the upper known bad dice.

8. The method as claimed in claim 1, further comprising:
(g) electrically connecting the die assemblies to a substrate;
(h) forming a molding compound to encapsulate the die assemblies; and
(i) sawing the substrate.
